(19) United States
(12) Patent Application Publication
(10) Pub. No.: US 2013/0043949 A1
(43) Pub. Date: Feb. 21, 2013

(54) METHOD OF FORMING A CIRCUIT HAVING A VOLTAGE REFERENCE AND STRUCTURE THEREFOR

(71) Applicant: Pierre Andre Genest, Lafitte Vigordane (FR)

(72) Inventor: Pierre Andre Genest, Lafitte Vigordane (FR)

(21) Appl. No.: 13/212,001

(22) Filed: Aug. 17, 2011

(51) Int. Cl. H03F 3/45; H05K 13/00

(52) U.S. Cl. 330/257; 29/592.1

(57) ABSTRACT

In one embodiment, two transistors are coupled in a current mirror configuration to form a delta voltage, and an amplifier is configured to control a first current carrying electrode of each of the first and second transistors at a substantially constant voltage.

### BACKGROUND OF THE INVENTION

The present invention relates, in general, to electronics, and more particularly, to semiconductors, structures thereof, and methods of forming semiconductor devices.

In the past, the electronics industry utilized various circuits and methods to form voltage reference circuits. As the value of the operating voltage of circuits decreases, it has become important for voltage reference circuits to operate from the lower power supply voltages, and to also have a low power consumption. Some previous circuits could operate with somewhat lower power supply voltage but not sufficiently low, and these circuits still had too high power consumption.

Accordingly, it is desirable to have a circuit and method of forming a voltage reference that can operate from lower power supply voltage and that has a reduced power consumption.

### BRIEF DESCRIPTION OF THE DRAWINGS

FIG. 1 schematically illustrates an embodiment of a portion of a circuit having a voltage reference circuit that can operate with low input voltage values and that has low power dissipation in accordance with the present invention;

FIG. 2 schematically illustrates an embodiment of a portion of another circuit having a voltage reference circuit that can operate with low input voltage values and that has low power dissipation in accordance with the present invention;

FIG. 3 schematically illustrates an embodiment of a portion of a comparator having a voltage reference circuit that can operate with low input voltage values and that has low power dissipation in accordance with the present invention;

FIG. 4 schematically illustrates an alternate embodiment of a portion of the comparator of FIG. 3 in accordance with the present invention;

FIG. 5 schematically illustrates a simplified embodiment of a portion of the circuit of FIG. 1 in accordance with the present invention; and

FIG. 6 illustrates an enlarged plan view of a semiconductor device that includes the circuit of FIG. 1 in accordance with the present invention.

For simplicity and clarity of the illustration(s), elements in the figures are not necessarily to scale, and the same reference numbers in different figures denote the same elements, unless stated otherwise. Additionally, descriptions and details of well-known steps and elements are omitted for simplicity of the description. As used herein current carrying electrode means an element of a device that carries current through the device such as a source or a drain of an MOS transistor or an emitter or a collector of a bipolar transistor or a cathode or anode of a diode, and a control electrode means an element of the device that controls current through the device such as a gate of an MOS transistor or a base of a bipolar transistor. Although the devices are explained herein as certain N-channel or P-Channel devices, or certain N-type or P-type doped regions, a person of ordinary skill in the art will appreciate that complementary devices are also possible in accordance with the present invention. One of ordinary skill in the art understands that the conductivity type refers to the mechanism through which conduction occurs such as through conduction of holes or electrons, therefore, and that conductivity type does not refer to the doping concentration but the doping type, such as P-type of N-type. It will be appreciated by those skilled in the art that the words during, while, and when as used herein relating to circuit operation are not exact terms that mean an action takes place instantly upon an initiating action but that there may be some small but reasonable delay, such as various propagation delays, between the reaction that is initiated by the initial action. Additionally, the term “while” means that a certain action occurs at least within some portion of a duration of the initiating action. The use of the word approximately or substantially means that a value of an element has a parameter that is expected to be close to a stated value or position. However, as is well known in the art there are always minor variances that prevent the values or positions from being exactly as stated. It is well established in the art that variances of up to at least ten percent (10%) (and up to twenty percent (20%) for semiconductor doping concentrations) are reasonable variances from the ideal goal of exactly as described. When used in reference to a state of a signal, the term “asserted” means an active state of the signal and the term “negated” means an inactive state of the signal. The actual voltage value or logic state (such as a “1” or a “0”) of the signal depends on whether positive or negative logic is used. Thus, asserted can be either a high voltage or a high logic or a low voltage or low logic depending on whether positive or negative logic is used and negated may be either a low voltage or low state or a high voltage or high logic depending on whether positive or negative logic is used. Herein, a positive logic convention is used, but those skilled in the art understand that a negative logic convention could also be used. The terms first, second, third and the like in the claims or/and in the Detailed Description of the Drawings, as used in a portion of a name of an element are used for distinguishing between similar elements and not necessarily for describing a sequence, either temporally, spatially, in ranking or in any other manner. It is to be understood that the terms so used are interchangeable under appropriate circumstances and that the embodiments described herein are capable of operation in other sequences than described or illustrated herein.

### DETAILED DESCRIPTION OF THE DRAWINGS

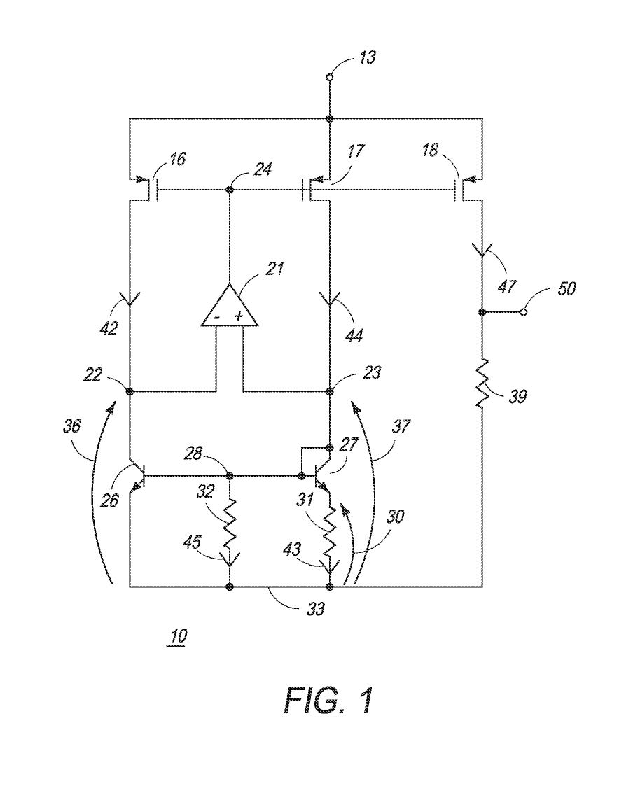

FIG. 1 schematically illustrates an embodiment of a portion of a circuit 10 having a voltage reference circuit that can operate with low input voltage values and that has low power dissipation. Circuit 10 is also formed to have temperature compensation. Circuit 10 receives an input voltage to operate circuit 10 between an input terminal or input 13 and a common node 33 and forms a substantially stable reference voltage or output voltage on an output 50 of circuit 10. The input voltage is usually a dc voltage. Node 33 typically is connected to a common reference voltage such as a ground reference or a voltage return reference, but may be connected to other voltages in other embodiments. As will be seen further hereinafter, circuit 10 utilizes two transistors coupled in a current mirror configuration that forms a delta Vbe of a bandgap reference portion of circuit 10. Circuit 10 includes NPN bipolar transistors 26 and 27 that are connected in the current mirror configuration. A control loop of circuit 10 includes an operational amplifier 21 and transistors 16-18 that are configured as current sources. Circuit 10 also includes resistors 31, 32, and 39.

Transistors 26 and 27 are formed to have active areas of different sizes so that the Vbe of transistors 26 and 27 are not the same value. Transistor 27 is formed to have an area that is larger than the area of transistor 26. In the preferred embodiment, transistor 27 has an active area that is about ten (10) times larger than the active area of transistor 26 so that in operation the value of the Vbe of transistor 27 is less than the value of the Vbe of transistor 26, although other area ratios may be used in other embodiments. Since transistor 27 has a larger active area than transistor 26, the Vbe of transistor 27 is less than the Vbe of transistor 26. This difference voltage or difference in the Vbe voltages (referred to as a delta voltage or delta Vbe or ΔVbe) is formed across resistor 31 as a voltage 30 (illustrated by an arrow). Those skilled in the art will appreciate that in this embodiment of for other embodiments that use other types of transistors, such as MOS transistors or silicon-germanium transistors, the difference voltage may be referred to as a delta voltage. The value of voltage 30 across resistor 31 causes a current 43 to flow through resistor 31 and transistor 27. Thus, the value of current 43 is representative of ΔVbe as shown by;

I43=ΔVbe/R31
Where
I43=the value of current 43, and
R31=the value of resistor 31.

A voltage 37 (illustrated by an arrow) is formed at a node 23 and on the collector of transistor 27. The value of voltage 37 is substantially the value of the Vbe of transistor 27 plus voltage 30 (ΔVbe). The control loop of amplifier 21 and transistors 16-17 are configured to regulate the value of the voltage at a node 22, thus on the collector of transistor 26, to be substantially equal to the value of the voltage on node 23. Amplifier 21 forces the value of a voltage 36 (illustrated by an arrow) at node 22 to be substantially equal to voltage 37 at node 23. In the preferred embodiment, transistors 16 and 17 have substantially equal active areas so that the value of respective currents 42 and 44 are substantially equal. The output of amplifier 21 forms an error voltage at a node 24 that controls transistors 16 and 17 to form respective currents 42 and 44 so that voltage 36 is substantially equal to voltage 37. Amplifier 21 also controls the value of current 47 to be substantially equal to current 44. Current 47 flows through resistor 39 forming an output voltage on output 50. In other embodiments, transistors 16 and 17 may have different sized active areas. A portion of current 44 flows through resistor 31 as current 43 so that voltage 30 is substantially equal to ΔVbe. Another portion of current 44 flows through resistor 32 as a current 45 so that the voltage across resistor 32 is substantially equal to the Vbe of transistor 26 which is also equal to the Vbe of transistor 27 plus ΔVbe.

If the value of the input voltage on input 13 changes, amplifier 21 keeps the values of currents 42, 44, and 47 substantially constant, thereby keeping the value of the voltage on output 50 substantially constant. Current 44 is representative of the Vbe of transistor 27 plus a voltage proportional to ΔVbe, thus, current 47 and the output voltage or reference voltage on output 50 are also representative of the Vbe of transistor 27 and the voltage proportional to ΔVbe. It can be seen that the reference or output voltage is also the sum of two proportional voltages such as:

V50=(ΔVbe(R39/R31))+(V26(R39/R32))
Where
V50=the reference voltage on output 50,
R31=the value of resistor 31,
R32=the value of resistor 32,
R39=the value of resistor 32.

Since ΔVbe, thus the output voltage on output 50, is formed using the Vbe of a transistor and a diode, circuit 10 can operate from low values of the input voltage. The minimum value of the input voltage preferably is just slightly higher than the maximum value of the Vbe of transistor 27 in order to facilitate operating from a minimum value of the supply voltage over process variations and the full temperature range. In other embodiments, the minimum value of the input voltage may have other values. In one embodiment of circuit 10 that operates at approximately twenty-seven degrees Celsius, circuit 10 could operate from an input voltage of less than approximately nine tenths (0.9) of a volt. If transistors 26 and 27 were silicon-germanium transistors, the input voltage could be even lower. Circuit 10 also has low power dissipation. The input offset voltage of amplifier 21 is divided by the gain of transistor 26, thus, any input offset voltage of amplifier 21 has very limited effect, if any, on the performance of circuit 10. Since the input offset voltage has minimal effect on circuit 10, amplifier 21 can be formed from metal oxide field effect transistors (MOSFETs) instead of bipolar transistors thereby lowering the power dissipation of circuit 10. Additionally, the high input impedance of such an amplifier allows higher gain to be achieved on node 22 which provides a high power supply rejection ratio (PSSR) and also improves the frequency compensation of circuit 10.

Circuit 10 also includes temperature compensation. Since transistor 26 has a negative temperature coefficient, the voltage across resistor 32 also has a negative temperature coefficient. Consequently, as the temperature changes, the value of current 45 changes opposite to the change in temperature. Since the diode configuration of transistor 27 has a positive temperature coefficient, the ΔVbe voltage across resistor 31 and resulting current 43 through resistor 31 have a positive temperature coefficient causing the value of current 43 to change in the same direction as the temperature change. The negative temperature change of current 45 acts to cancel the positive temperature change of current 43 so that the value of current 44 remains substantially constant as the temperature changes. Since amplifier 21 controls the value of current 47 to be substantially equal to current 44, the value of the voltage formed on output 50 remains substantially constant as the temperature changes.

From the above, it can be seen that the reference voltage or output voltage on output 50 of circuit 10 is formed from two currents (43 and 45) having opposite temperature coefficients.

The negative temperature coefficient current (current 45) flows through resistor 32 connected between the base of transistor 26 and common node 33 while the positive temperature current (current 43) flows in transistor 27 and through resistor 31 connected between the emitter of transistor 27 and common node 33. The base and the collector of transistor 27 are connected together and also commonly connected to a non-inverting input of amplifier 21, to a current source (transistor 17), and to the base of transistor 16, which has an emitter is connected to common node 33. The collector of transistor 26 is connected to an inverting input of amplifier 21 and to a second current source (transistor 16) whose current value is proportional to the current value of the first current source. The values of the current from the second current source is controlled by amplifier 21 through an output of amplifier 21 which is connected to a control input of the first and second current sources, for example to the gate of transistors 16 and 17.

As can be seen from the preceding, a temperature compensated current reference is presented having first and second bipolar transistors where the first bipolar transistor (BJT) has its emitter connected to a reference voltage and its base connected to the base of the second BJT and to a resistor connected to the reference voltage. The second BJT has larger size than the first BJT, has its emitter connected to the reference voltage through a resistor and has its collector connected to the bases of both BJTs. The BJTs collector currents are set by two proportional current sources controlled by the collector voltage of the first BJT.

It can also be seen that an additional current mirror configuration and a resistor, for example transistor 18 and resistor 39, may be added to convert the current to a temperature compensated voltage reference.

It is believed that circuit 10 has less power consumption that prior voltage reference circuits, and is also temperature compensated. In one embodiment, the ability to use the MOS implementation of amplifier 21 results in much less power dissipation that other implements such as a bipolar amplifier that may be required from a requirement of low input offset voltages.

In order to facilitate the above operation of circuit 10, a base of transistor 26 is commonly connected to node 28, a first terminal of resistor 32, to node 23, and to a base and collector of transistor 27. An emitter of transistor 26 is commonly connected to node 33, a second terminal of resistor 32 and a first terminal of resistor 31. A second terminal of resistor 31 is connected to an emitter of transistor 27. A collector of transistor 26 is commonly connected to node 22, an inverting input of amplifier 21, and to a drain of transistor 16. A non-inverting input of amplifier 21 is commonly connected to node 23 and to a drain of transistor 17. An output of amplifier 21 is commonly connected to node 24 and to a gate of transistor 16-18. A source of transistor 16 is commonly connected to input 13, a source of transistor 17, and a source of transistor 18. A drain of transistor 18 is connected to output 50 and to a first terminal of resistor 39. A second terminal of resistor 39 is connected to node 33.

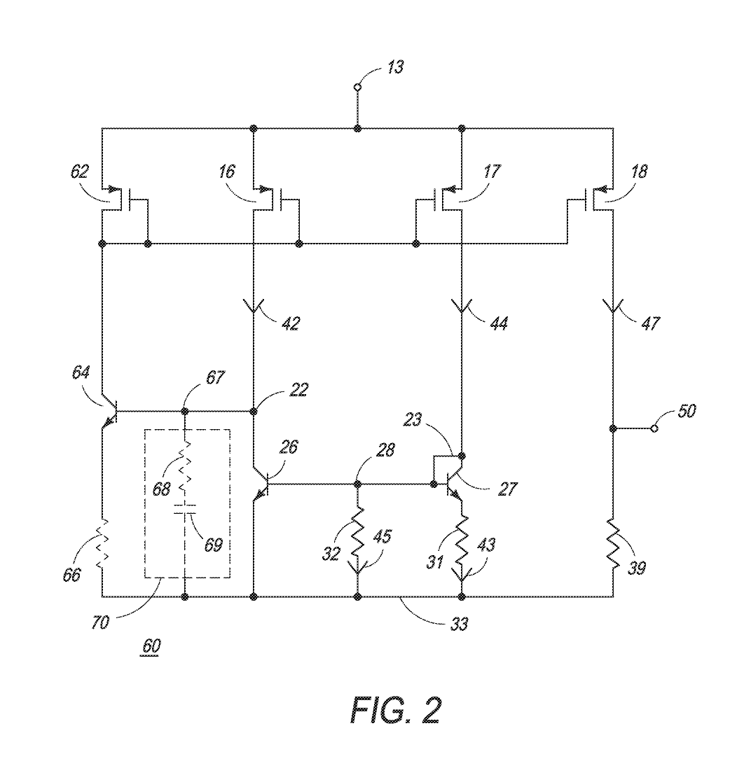

FIG. 2 schematically illustrates an embodiment of a portion of a circuit 60 that is an alternate embodiment of circuit 10 explained in the description of FIG. 1. Circuit 60 is configured to have a voltage reference circuit that can operate with low input voltage values and that has low power dissipation. Circuit 60 is also formed to have temperature compensation. Circuit 60 is similar to circuit 10 except that circuit 60 does not include amplifier 21. Circuit 60 includes a transistor 64 that functions as an amplifier and a transistor 62 that is a part of the current mirror of transistors 16-18. An optional resistor 66 and an optional compensation network 70 may also be included in circuit 60. Transistor 64 has a size and temperature characteristic that are matched to the size and temperature characteristic of transistor 26. In the preferred embodiment, the Vbe of transistor 64 should be substantially equal to the Vbe of transistor 26. Those skilled in the art can understand that the transistors do not have to be matched due to the fact that the matching error is divided by the voltage gain of transistor 26. Transistor 64 keeps the voltage on the collector of transistors 26-27 and at nodes 22-23 substantially constant similar to amplifier 21. Since transistor 64 adds an input impedance to node 22, it reduces the gain of transistor 26. Therefore, an optional compensation network 70 may be added to improve the frequency response of circuit 60. Network 70 may include a resistor 68 and a capacitor 69 connected in series and connected between node 22 and node 33. Optional resistor 66 may be added in series between the emitter of transistor 64 and node 33 to also improve stability by reducing the gain of transistor 64. Circuit 60 usually provides a less accurate output voltage at higher input voltage values than that provided by circuit 10, however, circuit 60 is simpler than circuit 10.

In order to facilitate the above described circuit 60, the base of transistor 26 is commonly connected to node 28, the first terminal of resistor 32, and to the base and collector of transistor 27. The emitter of transistor 26 is commonly connected to node 33, the second terminal of resistor 32 and the first terminal of resistor 31. The second terminal of resistor 31 is connected to the emitter of transistor 27. The collector of transistor 26 is commonly connected to node 22, to a base of transistor 64, and to the source of transistor 16. An emitter of transistor 64 is connected to node 33, and may optionally be connected to a first terminal of a resistor 66 which has a second terminal connected to node 33. A collector of transistor 64 is commonly connected to a drain and gate of transistor 62 and to the gate of transistors 16-18. A source of transistor 62 is commonly connected to input 13 and to the source of transistors 16-18. The drain of transistor 17 is connected to the collector of transistor 27. The drain of transistor 18 is connected to output 50 and to a first terminal of resistor 39 which has a second terminal connected to node 33.

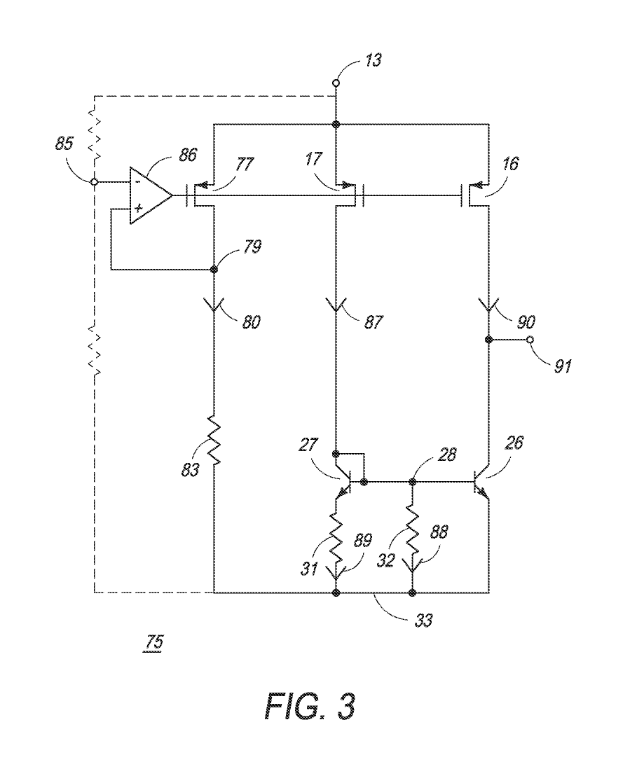

FIG. 3 schematically illustrates an embodiment of a portion of a comparator 75 having a voltage reference circuit that can operate with low input voltage values and that has low power dissipation. Comparator 75 includes transistors 16, 17, 26, and 27 along with resistors 31 and 32 of circuit 10. However, comparator 75 does not include amplifier 21 and operates differently than circuit 10. Comparator 75 also includes an amplifier 86, a current source that is illustrated as a transistor 77, and a resistor 83. Comparator 75 is configured to receive an input voltage on an input 85 and form a signal on an output 91 indicating whether the input voltage on input 85 is less than a particular threshold voltage or is greater than or equal to the threshold voltage.

If the value of the voltage on input 85 is low, the value of a current 80 through resistor 83 is also low. Because of the current mirror configuration between transistors 77 and 17, the value of a current 87 through transistor 17 is also low. Therefore, the value of a current 90 through transistor 26 is also low. Because transistor 27 is larger than transistor 26, the value of current 90 through transistor 26 is smaller than current 88 and typically tries to be a value approximately equal to the value of current 88 divided by the ratio of the size of the areas of transistors 26 and 27. Due to the low value of current 90, transistor 16 couples a voltage to output 91 that is approximately equal to the value of the voltage on input 13.

As the value of the voltage on input 85 increases, the value of currents 80 and 87 also increase thereby increasing the value of currents 88 and 89 which also the voltage across resistor 32. Since the voltage across resistor 32 controls the Vbe voltage of transistor 26, the Vbe of transistor 26 also increases. Due to the exponential relationship between the Vbe and current of a bipolar transistor, the Vbe increase of transistor 26 causes a much larger increase in the value of current 90. As the value of the voltage on input 85 continues to increase, the value of current 90 continues to increase faster than currents 87-89 until at some point the value of current 90 becomes approximately equal to the value of current 87 which causes transistor 26 pull output 91 of comparator 75 approximately to the value of the voltage on node 33 thereby causing output 91 to switch from high voltage value to a low voltage value. As can be seen, output 91 switches when the voltage on input 85 is approximately equal to or greater than a threshold voltage of comparator 75 which can be represented by the equation:

Vth=R83((ΔVbe/R31)+(Vbe26/R32))
Where
Vth=the threshold voltage of comparator 75,
R83=the value of resistor 83,
R31=the value of resistor 31,
Vbe26=the Vbe of transistor 26, and
R32=the value of resistor 32.

In this embodiment and in order to facilitate the functionality of comparator 75, the base of transistor 26 is commonly connected to node 28, the first terminal of resistor 32, and to the base and collector of transistor 27. The emitter transistor 26 is commonly connected to node 33, the second terminal of resistor 32, the first terminal of resistor 31, and to the first terminal of resistor 83. The second terminal of resistor 31 is connected to the emitter of transistor 27. The collector of transistor 26 is commonly connected to output 91 and to the drain of transistor 16. The collector of transistor 27 is connected to the drain of transistor 17. A second terminal of resistor 83 is commonly connected to a drain of transistor 77 and to a non-inverting input of amplifier 86. An inverting input of amplifier 86 is connected to input 85 of comparator 75. A source of transistor 77 is commonly connected to input 13 and to the source of transistors 16 and 17.

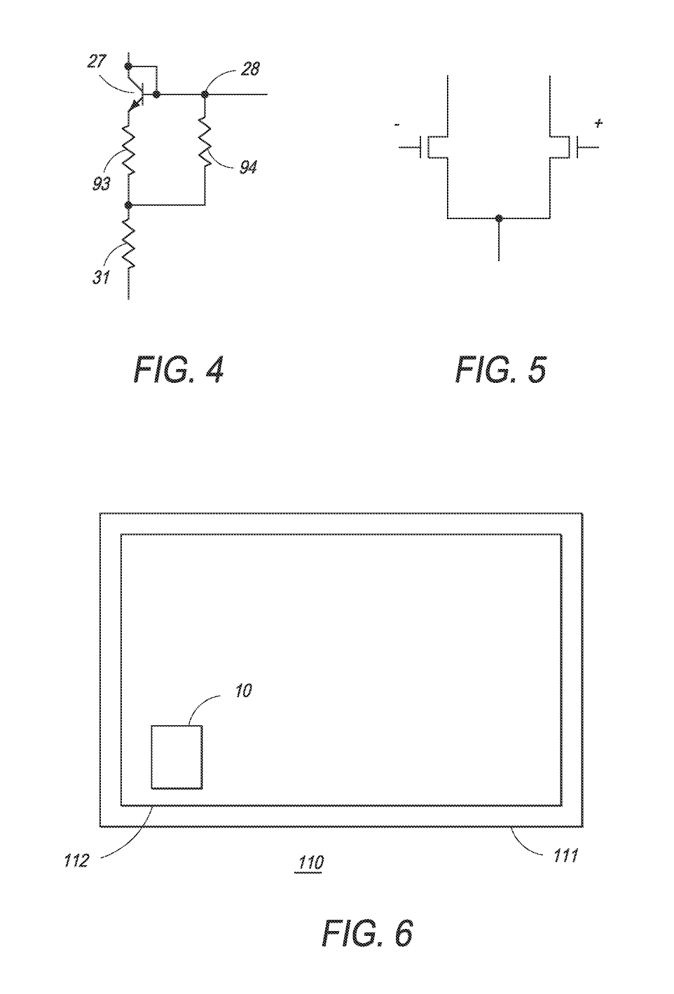

FIG. 4 schematically illustrates an alternate embodiment of a portion of comparator 75. Resistor 32 may be replaced by resistors 93 and 94. Resistor 93 is connected between the emitter of transistor 27 and the second terminal of resistor 31. Resistor 94 is connected between the base of transistor 27 and the node that is formed between resistors 31 and 93. This embodiment, the current with the negative temperature coefficient can be created by connecting resistor 32 across the Vbe of transistor 26 or across the Vbe of transistor 27. Each case needs a specific adjustment of resistor value, but both are compensating the positive temperature coefficient of delta Vbe at first order. Theoretically, the temperature compensation is limited by second order effects which prevent some voltage references from having a flat reference voltage over the temperature range. For example, a typical prior bandgap reference had a maximum value in the middle of the temperature range, but other prior topologies may have presented a minimum in the middle of that range. The configuration of resistors 94 and 93 provides an average of the two possible temperature characteristics and second order effects are minimized which provides a reference voltage that has a flatter voltage over temperature. This solution can be applied to circuits 10 and 60 of FIGS. 1 and 2.

FIG. 5 schematically illustrates a simplified embodiment of a portion of amplifier 21 of FIG. 1 with MOS transistors as the inverting and non-inverting inputs of amplifier 21. AS indicated hereinbefore, forming amplifier 21 from metal oxide field effect transistors (MOSFETs) lowers the power dissipation.

Comparator 75 may be used for detecting various voltage types. For example, comparator 75 may be used to detect an over-voltage value or and under-voltage value of a signal or of a power supply voltage as illustrated by the resistor divider in dashed lines. Thus, comparator 75 may be configured to receive a signal that is representative of a voltage and form a control signal on output 50 that is representative of the voltage being less than or greater than a desired value of the voltage.

FIG. 6 illustrates an enlarged plan view of a portion of an embodiment of a semiconductor device or integrated circuit 110 that is formed on a semiconductor die 111. Circuit 10 or any of circuits 60 or comparator 75 may be formed on die 111. Die 111 may also include other circuits that are not shown in FIG. 6 for simplicity of the drawing. Circuits 10 and 60 or comparator 75 and device or integrated circuit 110 are formed on die 111 by semiconductor manufacturing techniques that are well known to those skilled in the art.

Those skilled in the art will understand from all the foregoing that in one embodiment a circuit having a voltage reference may comprise; a first transistor, for example transistor 26, having a first current carrying electrode coupled to a common node, and a second current carrying electrode, and a control electrode; a second transistor, such as transistor 27 for example, having a first current carrying electrode, and having a control electrode commonly coupled to the control electrode of the first transistor and to a second current carrying electrode of the second transistor; a first resistor, resistor 31 for example, having a first terminal coupled to the first current carrying electrode of the second transistor and having a second terminal coupled to the common node; and an amplifier, for example amplifier 21, having an output, and also having an inverting input coupled to the second current carrying electrode of the first transistor and having a non-inverting input coupled to the second current carrying electrode of the second transistor.

In another embodiment, the circuit may also include a third transistor, transistor 16 for example, having a control electrode coupled to the output of the amplifier, a first current carrying electrode coupled to a voltage input of the circuit, and also having a second current carrying electrode coupled to the second current carrying electrode of the first transistor.

In yet another embodiment, the circuit may also include a fourth transistor, such as transistor 17 for example, having a control electrode coupled to the output of the amplifier, a first current carrying electrode coupled to the voltage input of the circuit, and also having a second current carrying electrode coupled to the second current carrying electrode of the second transistor.

Another embodiment of the circuit may include a fifth transistor, transistor 18 for example, having a control electrode coupled to the output of the amplifier, a first current carrying electrode coupled to the voltage input of the circuit, and also having a second current carrying electrode coupled to an output of the circuit, and also including a resistor coupled between the output of the circuit and the common node.

Those skilled in the art will also appreciate that in another embodiment a method of forming a circuit having a voltage reference may comprise; coupling first and second transistors, such as respective transistors 26 and 27 for example, in a current mirror configuration to form a delta voltage across a first resistor, resistor 31 for example, relative to a common node wherein the second transistor has a larger active area than the first transistor; and an amplifier, for example amplifier 21, configured to control a voltage at a first current carrying electrode of each of the first and second transistors to a substantially constant voltage.

Those skilled in the art will also appreciate that in another embodiment, the method may also include coupling third and fourth transistors, transistors 16 and 17 for example, in a second current mirror configuration to form first and second currents, such as currents 42 and 43, to flow through the third and fourth transistors respectively wherein the first and second currents are controlled responsively to an output of the amplifier.

Another embodiment may also include coupling a fifth transistor, for example transistor 18, to form a third current, current 47 for example, to flow through a second resistor, resistor 39 for example, wherein the first and second currents are controlled responsively to an output of the amplifier.

Yet another embodiment may include forming a second current mirror, such as that formed by transistors 17 and 18, to form a current, current 47 for example, that is representative of a delta voltage formed by the current mirror configuration of the first and second transistors.

Those skilled in the art will further understand that in another embodiment, a method of forming a comparator may comprise: coupling first and second transistors, transistors 27 and 26 for example, in a first current mirror configuration wherein the first transistor has a larger active area than the second transistor; and coupling an amplifier, such as amplifier 86 for example, to receive an input signal, the signal on input 85 for example, and control a value of a first current, current 89 for example, from the first current mirror through the first transistor responsively to the input signal wherein the second transistor controls a second current, for example current 90, from the first current mirror through the second transistor to be less than the first current for values of the input signal that are less than a threshold value of the comparator and controls the second current to be no less than the first current for values of the input signal that are no less than the threshold value.

In another embodiment, the method may also include coupling a second resistor to receive the delta voltage plus a threshold voltage of the first transistor and cause a third current, current 88 for example, to flow through the second resistor wherein the first current and the third current are summed as a fourth current, for example current 87.

Another embodiment of the method may further include coupling third and fourth transistors, such as respective transistors 17 and 16, in a second current mirror configuration with the amplifier to form the first and second currents.

Another embodiment may also include coupling a fifth transistor, transistor 77 for example, in the second current mirror configuration with the amplifier wherein an output of the amplifier controls the fifth transistor to form a third current, such as current 80 for example, that flows through a first resistor.

In view of all of the above, it is evident that a novel device and method is disclosed. Included, among other features, is forming a method and circuit that has a voltage reference that can operate from low input supply voltage values or low operating voltage values, and that also has temperature compensation. Also included is a method and circuit of a comparator that has a voltage reference that can operate from low input supply voltage values or low operating voltage values, and that also has temperature compensation.

While the subject matter of the descriptions are described with specific preferred embodiments and example embodiments, the foregoing drawings and descriptions thereof depict only typical and exemplary embodiments of the subject matter and are not therefore to be considered to be limiting of its scope, it is evident that many alternatives and variations will be apparent to those skilled in the art. As will be appreciated by those skilled in the art, the exemplary form of circuits 10, 60, and 75 are used as a vehicle to explain the circuit and the operation method. Circuits 10 and 60 may be configured with various other embodiments in addition to the preferred embodiment illustrated in FIGS. 1-4 as long as a current mirror is configured to form the Vbe and the amplifier is configured to form the current trough the current mirror and maintain the voltage at nodes 22 and 23 substantially constant. The subject matter has been described for a particular NPN transistor structure, although the method is directly applicable to other bipolar transistors, as well as to MOS, BiCMOS, metal semiconductor FETs (MESFETs), HFETs, and other transistor structures.

As the claims hereinafter reflect, inventive aspects may lie in less than all features of a single foregoing disclosed embodiment. Thus, the hereinafter expressed claims are hereby expressly incorporated into this Detailed Description of the Drawings, with each claim standing on its own as a separate embodiment of an invention. Furthermore, while some embodiments described herein include some but not other features included in other embodiments, combinations of features of different embodiments are meant to be within the scope of the invention, and form different embodiments, as would be understood by those skilled in the art.

1. A circuit having a voltage reference comprising:
a first transistor having a first current carrying electrode coupled to a common node, and a second current carrying electrode, and a control electrode;
a second transistor having a first current carrying electrode, and having a control electrode commonly coupled to the control electrode of the first transistor and to a second current carrying electrode of the second transistor;
a first resistor having a first terminal coupled to the first current carrying electrode of the second transistor and having a second terminal coupled to the common node; and
an amplifier having an output, and also having an inverting input coupled to the second current carrying electrode of the first transistor and having a non-inverting input coupled to the second current carrying electrode of the second transistor.

2. The circuit of claim 1 further including a third transistor having a control electrode coupled to the output of the amplifier, a first current carrying electrode coupled to a voltage input of the circuit, and also having a second current carrying electrode coupled to the second current carrying electrode of the first transistor.

3. The circuit of claim 2 further including a fourth transistor having a control electrode coupled to the output of the amplifier, a first current carrying electrode coupled to the voltage input of the circuit, and also having a second current carrying electrode coupled to the second current carrying electrode of the second transistor.

4. The circuit of claim 3 further including a fifth transistor having a control electrode coupled to the output of the amplifier, a first current carrying electrode coupled to the voltage input of the circuit, and also having a second current carrying electrode coupled to an output of the circuit, and also including a resistor coupled between the output of the circuit and the common node.

5. The circuit of claim 1 wherein the first and second transistors are bipolar transistors.

6. A method of forming a circuit having a voltage regulator comprising:
coupling first and second transistors in a current mirror configuration to form a delta voltage across a first resistor relative to a common node wherein the second transistor has a larger active area than the first transistor; and
an amplifier configured to control a voltage at a first current carrying electrode of each of the first and second transistors to a substantially constant voltage.

7. The method of claim 6 wherein coupling the first and second transistors in the current mirror configuration includes coupling first and second bipolar transistors in the current mirror configuration and configuring the circuit to form a delta Vbe across the first resistor relative to a common node.

8. The method of claim 6 further including coupling third and fourth transistors in a second current mirror configuration to form first and second currents to flow through the third and fourth transistors respectively wherein the first and second currents are controlled responsively to an output of the amplifier.

9. The method of claim 8 wherein coupling the third and fourth transistors in the second current mirror configuration further includes coupling a fifth transistor to form a third current to flow through a second resistor wherein the first and second currents are controlled responsively to an output of the amplifier.

10. The method of claim 6 further including forming a second current mirror to form a current that is representative of a delta voltage formed by the current mirror configuration of the first and second transistors.

11. The method of claim 10 further including coupling a second resistor between the second current mirror and an output of the voltage regulator

12. The method of claim 10 including coupling the first resistor to the first transistor.

13. The method of claim 10 further including configuring a second resistor to convert the current to an output voltage of the circuit.

14. A method of forming a comparator comprising:
coupling first and second transistors in a first current mirror configuration wherein the first transistor has a larger active area than the second transistor; and
coupling an amplifier to receive an input signal and control a value of a first current from the first current mirror through the first transistor responsively to the input signal wherein the second transistor controls a second current from the first current mirror through the second transistor to be less than the first current for values of the input signal that are less than a threshold value of the comparator and controls the second current to be no less than the first current for values of the input signal that are no less than the threshold value.

15. The method of claim 14 wherein coupling the first and second transistors in the first current mirror configuration includes coupling the first and second transistors to form a delta voltage across a first resistor and also includes coupling a second resistor to receive the delta voltage plus a threshold voltage of the first transistor and cause a third current to flow through the second resistor wherein the first current and the third current are summed as a fourth current.

16. The method of claim 14 wherein coupling the first and second transistors in the first current mirror configuration includes coupling first and second bipolar transistors to form a delta Vbe across a first resistor relative to a common node.

17. The method of claim 14 further including coupling third and fourth transistors in a second current mirror configuration with the amplifier to form the first and second currents.

18. The method of claim 17 including coupling an output of the amplifier to control the third and fourth transistors to control a value of the first current responsively to the input signal.

19. The method of claim 17 further including coupling a fifth transistor in the second current mirror configuration with the amplifier wherein an output of the amplifier controls the fifth transistor to form a third current that flows through a first resistor.
